(19) United States
(12) Patent Application Publication
(10) Pub. No.: US 2018/0166313 A1
(43) Pub. Date: Jun. 14, 2018

(54) THERMOPLASTIC ELASTOMER (TPE) ADHESIVE CARRIER TAPE

(71) Applicant: Intel Corporation, Santa Clara, CA (US)

(72) Inventors: Mingzhi Dai, Chandler, AZ (US); Wen Yin, Chandler, AZ (US); Craig S. Dunning, Chandler, AZ (US); Robert D. Callan, Chandler, AZ (US)

(21) Appl. No.: 15/376,042

(22) Filed: Dec. 12, 2016

(51) Int. Cl. H01L 21/683; H01L 23/00

(52) U.S. Cl. CPC H01L 21/6836; H01L 24/93

(57) ABSTRACT

Embodiments relate to a carrier tape that includes a first layer of thermoplastic elastomer (TPE) adhesive tape. The carrier tape may further include a second layer of rigid polymer with a cavity. The rigid polymer may be coupled with a surface of the TPE adhesive tape such that the TPE adhesive tape is exposed by the cavity. A die may be coupled with the TPE adhesive tape within the cavity. Other embodiments may be described and/or claimed.

### FIELD

Embodiments of the present disclosure generally relate to the field of die packaging and transport and, more particularly, to the tape used for such packaging and transport.

### BACKGROUND

Typically, a die such as a memory die, a central processing unit (CPU), or some other sort of die may be transported from one location to another via a carrier tape. Specifically, a unit of carrier tape may include a plurality of die. However, legacy carrier tape may have some inefficiencies.

For example, in many legacy tape and reel (TnR) solutions, the carrier tape may be tailored to the specific form factor of the die. A carrier tape that is tailored to one size or form of a die may not be usable for another size or form of the die. As a result, if a tape that is tailored for a new die is desired, design and manufacturing of the tape may be costly and require significant lead time.

Additionally, legacy TnR solutions may allow the die to move during transport, which may result in damage to the die. In some cases die mis-alignment or die rotation during a pick and placement (PnP) operation may be introduced if the die has moved during transport.

In some legacy solutions, the die may be coupled with the carrier tape via a high adhesion molecular adhesive. The die may be removed from the tape by a die ejection mechanism that pushes on the carrier tape to eject the die from the carrier tape. However, this ejection mechanism may be expensive to implement because it may require a more complicated manufacturing facility. Additionally, the high adhesion molecular adhesive may leave an undesirable residue on the die once the die is removed from the carrier tape.

### BRIEF DESCRIPTION OF THE DRAWINGS

Embodiments will be readily understood by the following detailed description in conjunction with the accompanying drawings. To facilitate this description, like reference numerals designate like structural elements. Embodiments are illustrated by way of example and not by way of limitation in the figures of the accompanying drawings.

FIG. 1 depicts an example top-down view of a carrier tape in accordance with embodiments herein.

FIG. 2 depicts an example side cutaway view of the carrier tape of FIG. 1, in accordance with embodiments herein.

FIGS. 3 and 4 depict an example PnP operation using the carrier tape of FIG. 1, in accordance with embodiments herein.

FIG. 5 depicts an example process of manufacturing the carrier tape of FIG. 1, in accordance with embodiments herein.

### DETAILED DESCRIPTION

Embodiments of the present disclosure relate to a carrier tape that includes a first layer of thermoplastic elastomer (TPE) adhesive tape. The carrier tape may further include a second layer of rigid polymer with one or more cavities. The rigid polymer may be coupled with a surface of the TPE adhesive tape such that the TPE adhesive tape is exposed by the one or more cavities. One or more dice may be coupled with the TPE adhesive tape within the one or more cavities. Generally, the lateral area of a cavity may be greater than the lateral area of a die placed within that cavity. Other embodiments may be described and/or claimed.

In the following description, various aspects of the illustrative implementations will be described using terms commonly employed by those skilled in the art to convey the substance of their work to others skilled in the art. However, it will be apparent to those skilled in the art that embodiments of the present disclosure may be practiced with only some of the described aspects. For purposes of explanation, specific numbers, materials, and configurations are set forth in order to provide a thorough understanding of the illustrative implementations. It will be apparent to one skilled in the art that embodiments of the present disclosure may be practiced without the specific details. In other instances, well-known features are omitted or simplified in order not to obscure the illustrative implementations.

In the following detailed description, reference is made to the accompanying drawings that form a part hereof, wherein like numerals designate like parts throughout, and in which is shown by way of illustration embodiments in which the subject matter of the present disclosure may be practiced. It is to be understood that other embodiments may be utilized and structural or logical changes may be made without departing from the scope of the present disclosure. Therefore, the following detailed description is not to be taken in a limiting sense, and the scope of embodiments is defined by the appended claims and their equivalents.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B, and C).

The description may use perspective-based descriptions such as top/bottom, in/out, over/under, and the like. Such descriptions are merely used to facilitate the discussion and are not intended to restrict the application of embodiments described herein to any particular orientation.

The description may use the phrases “in an embodiment,” or “in embodiments,” which may each refer to one or more of the same or different embodiments. Furthermore, the terms “comprising,” “including,” “having,” and the like, as used with respect to embodiments of the present disclosure, are synonymous.

The term “coupled with,” along with its derivatives, may be used herein. “Coupled” may mean one or more of the following. “Coupled” may mean that two or more elements are in direct physical or electrical contact. However, “coupled” may also mean that two or more elements indirectly contact each other, but yet still cooperate or interact with each other, and may mean that one or more other elements are coupled or connected between the elements that are said to be coupled with each other. The term “directly coupled” may mean that two or more elements are in direct contact.

In various embodiments, the phrase “a first layer formed, deposited, or otherwise disposed on a second layer” may mean that the first layer is formed, deposited, grown, bonded, or otherwise disposed over the second layer, and at least a part of the first layer may be in direct contact (e.g., direct physical and/or electrical contact) or indirect contact (e.g., having one or more other layers between the first layer and the second layer) with at least a part of the second layer.

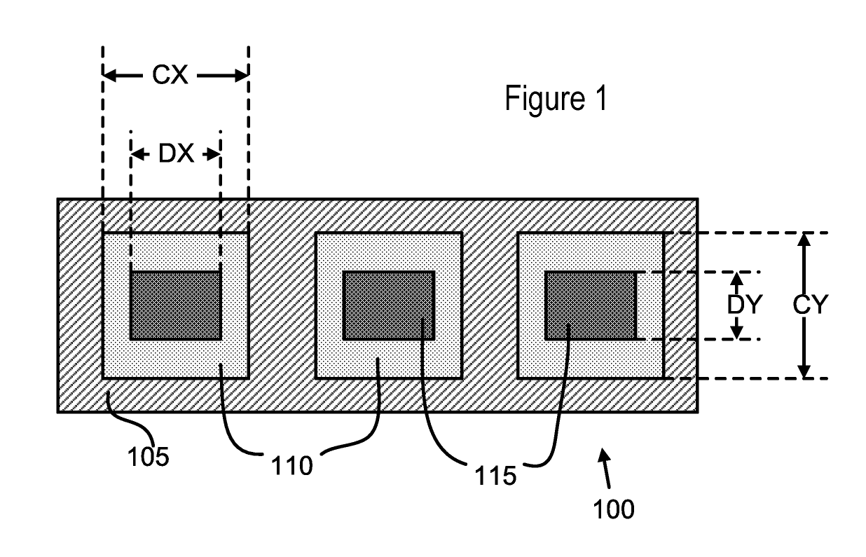

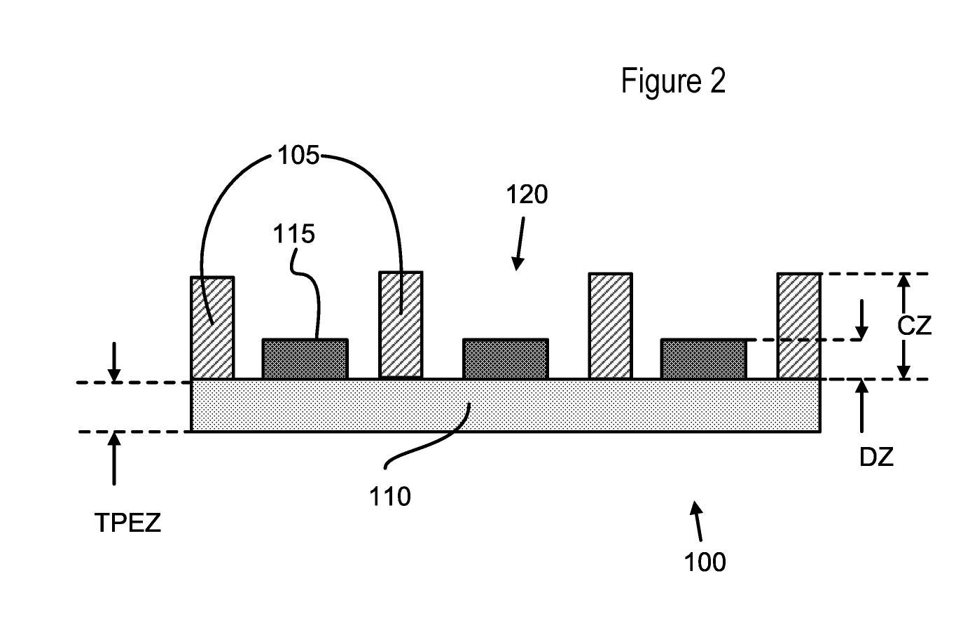

FIG. 1 depicts an example top-down view of a carrier tape 100. FIG. 2 depicts an example side cutaway view of the carrier tape 100. Specifically, the carrier tape 100 may include an adhesive thermoplastic elastomer (TPE) tape 110. The TPE tape 110 may be coupled with a rigid polymer 105. The rigid polymer 105 may include one or more cavities such as cavity 120, and respective cavities 120 may have a die 115 disposed therein. The die(s) 115 may be adhered to the adhesive TPE tape 110.

In embodiments, the TPE tape 110 may be formed of a TPE such as styrene-ethylene-butadiene-styrene (SEBS). The SEBS may adhere the die 115 to the TPE tape 110, but leave little to no residue when the die 115 is removed from the cavity 120. In other embodiments, the TPE tape 110 may be formed of thermoplastic polyurethanes, thermoplastic olefins, or some other similar material. Generally, the TPE material may be selected based on factors such as adhesion to the die, the amount of residue the TPE material leaves on the die once the die is removed from the TPE material, and/or other factors. Generally, it may be desirable for the TPE material to have an adhesion factor of between approximately 100 gram force (gf) and approximately 500 gf. In some embodiments, the TPE material may have an adhesion factor of approximately 150 gf. In embodiments, the TPE tape 110 may have a thickness (indicated by TPEZ in FIG. 2) of less than approximately 100 micrometers (um).

The rigid polymer 105 may be or include, for example, a polystyrene (PS) and/or a polyethylene (PE) material. For example, the rigid polymer 105 may include 3 layers of a material such as PS-acrylonitrile butadiene styrene (ABS). In some embodiments, the rigid polymer 105 may be a punched tape. That is, the rigid polymer 105 may originally be formed of a single sheet of polymer that then has one or more holes punched, stamped, cut, etched, or otherwise formed through physical, mechanical, chemical, and/or optical means. The TPE tape 110 may then be laminated, extruded directly onto, or otherwise coupled to the punched rigid polymer 105. Upon coupling, the punched holes may form the cavities 120. In other embodiments, the TPE tape 110 may be laminated, extruded, or otherwise coupled to an unpunched rigid polymer, and then the cavities 120 may be formed, for example, by chemical etching, mechanical etching, optical etching, and/or some other technique of forming the cavities 120.

The die 115 may be a die such as a CPU, a volatile or non-volatile memory, a transistor, or some other type of die. As shown in FIG. 2, the die 115 may have a height (indicated by DZ) with respect to the carrier tape 100. As shown in FIG. 1, the die 115 may additionally have a length (indicated by DY) and a width (indicated by DX) with respect to the carrier tape 100. In some embodiments, DZ may be between approximately 0.1 millimeters (mm) to approximately 0.78 mm. DY may be between approximately 0.5 mm and approximately 33 mm. DX may be between approximately 0.5 mm and approximately 33 mm.

The rigid polymer 105 may also have a height (indicated by CZ in FIG. 2). In some embodiments, the height CZ of the rigid polymer 105 may be between approximately 0.6 mm and approximately 1 mm. Similarly, the cavities 120 of the rigid polymer 105 may have a width (indicated by CX in FIG. 1), and a length (indicated by CY in FIG. 1). In some embodiments, the width CX may be between approximately 1 mm and approximately 33.5 mm. The length CY may be between approximately 1 mm and approximately 33.5 mm.

As can be seen in FIGS. 1 and 2, generally the dimensions of the cavities 120 (e.g., CZ, CX, and CY) may be larger than the dimensions of the die 115 (e.g., DZ, DX, and DY). To phrase it another way, the lateral area of the die 115 (as measured parallel to the surface of the TPE tape 110 to which the die 115 is coupled) may be smaller than the lateral area of the cavities 120. These dimensions may provide several benefits. One such benefit may be that the die 115 may be generally protected by the rigid polymer 105 if the height CZ of the rigid polymer 105 is higher than the height DZ of the die 115. That is, the rigid polymer 105 may act as a buffer or bumper protecting the die from crushing.

Similarly, if the cavity 120 has a larger length CY and width CX than the length and width DY and DX of the die 115, the carrier tape 100 may be reused to carry a die with a different form factor once the die 115 is removed from the cavity 120. For example, if the die 115 is removed from the cavity 120, then another die that has a length between DY and CY, and/or a width between DX and CX, may be placed within the cavity 120. Notably, the carrier tape 100, and specifically the rigid polymer 105, may not have to be altered or re-designed to accommodate the new die. In this manner, the carrier tape 100 may provide significant cost and time savings over legacy TnR solutions, because the lack of alteration and/or re-design may reduce or eliminate the above-described design costs and lead times.

Additionally, because the die 115 is adhesively coupled with the TPE tape 110, the die 115 is prevented from moving within the cavity 120. This adhesion may reduce or eliminate mis-alignment or rotation of the die 115 during the manufacturing process. However, as noted above, the TPE tape 110 may leave little to no residue on the die 115 when the die is removed from the cavity 120.

Additionally, legacy TnR solutions may generally be shipped in a rolled up reel form that may then be unspooled once the dice are to be removed from the carrier tape. In embodiments herein, the carrier tape 100 may be folded flatly on top of itself, which may decrease the amount of lateral and vertical space required for shipping the carrier tape 100.

It will be understood that FIGS. 1 and 2 are intended as examples of a carrier tape, and other carrier tapes may have more or fewer components. For example, although FIGS. 1 and 2 show that the carrier tape 100 includes three cavities and three dice, in other embodiments the carrier tape 100 may include more or fewer dice. Additionally, in some embodiments the dice may not be arranged in a single row as shown in FIG. 1; rather, in some embodiments the dice may be arranged side-by-side on the tape such that they are laterally adjacent to one another in both rows and columns.

In some embodiments, different dice on the carrier tape may have different dimensions. For example, the length, width, and/or height of one die on the carrier tape may be different than the length, width, and/or height of another die on the carrier tape. Similarly, different cavities in the rigid polymer 105 may have different lengths, widths, and/or heights from one another. The different cavity sizes may allow for a greater number of options to transport different dice using the carrier tape.

Additionally, although terms like “length,” “width,” and “height” are used in descriptions above, it will be understood that those terms are used to provide a standard frame of reference for the descriptions in these discussions. Such terms are not intended to be restrictive.

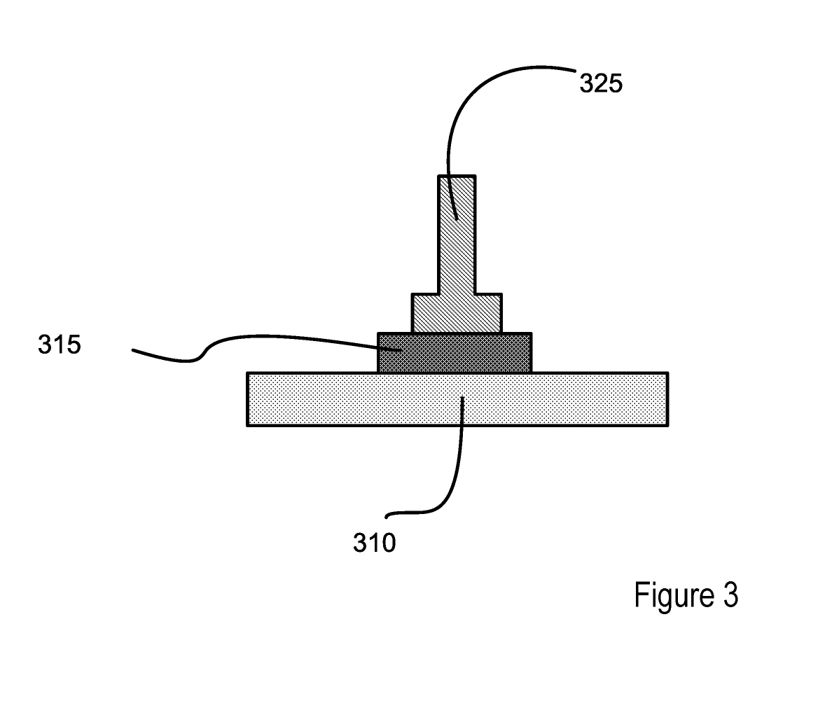

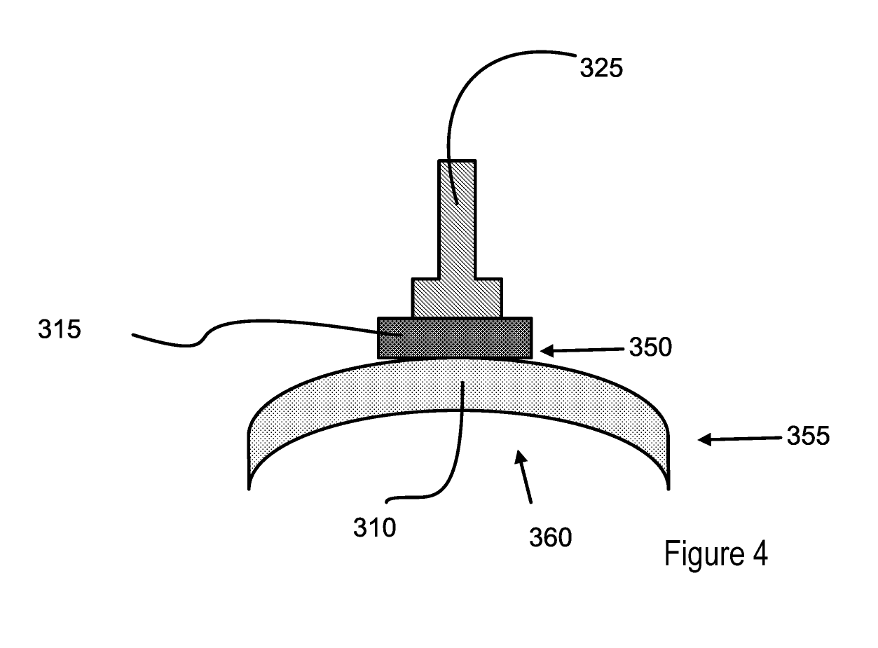

FIGS. 3 and 4 depict an example PnP operation by which a die such as die 115 may be removed from a cavity such as cavity 120. Specifically, FIG. 3 includes a TPE tape 310 and die 315, which may be respectively similar to TPE tape 110 and die 115. FIG. 3 further includes a PnP head 325. For the sake of clarity of FIGS. 3 and 4, a rigid polymer such as rigid polymer 105 is not shown coupled with the TPE tape 110.

The PnP head 325 may engage the die 315 in some way as shown in FIG. 3. For example, the PnP head 325 may be able to generate suction at the face which engages the die 315, thereby adhering the die 315 to the PnP head 325. Additionally or alternatively, the PnP head 325 may engage the die 315 via a mechanical, adhesive, or other engagement mechanism.

As shown in FIG. 4, the PnP head 325 may then begin to pull the die 315 away from the TPE tape 310. Doing so may cause the TPE tape 310 to “tent,” that is to raise at or near a central portion 360 of the TPE tape 310 while the sides 355 of the TPE tape 310 remain lower than the central portion 360. When the TPE tape 310 begins to tent, the TPE tape 310 may begin to peel away from the periphery 350 of the die 315. As the PnP head 325 continues to pull the die 315, the die 315 may ultimately separate from the TPE tape 310. Notably, this separation of the die 315 from the TPE tape 310 may occur without the need for an element to push upward on the bottom of the TPE tape 310 (directions given with reference to FIGS. 3 and 4) to separate the die 315 from the TPE tape 310 during the PnP process.

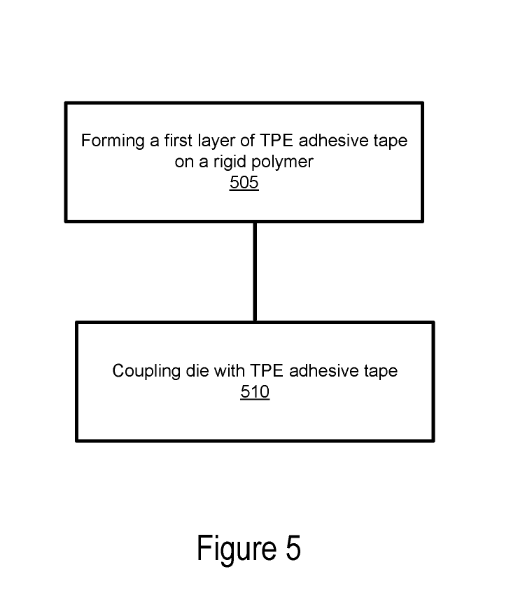

FIG. 5 depicts an example process of manufacturing the carrier tape 100 of FIG. 1. The process may include forming a first layer of TPE adhesive tape on a rigid polymer at 505. The first layer of TPE adhesive tape may be, for example, similar to TPE tape 110 or 310. The rigid polymer may be, for example, similar to rigid polymer 105. As described above, the TPE tape may be formed on the rigid polymer through lamination to the rigid polymer. Alternatively, the TPE tape may be extruded directly onto the rigid polymer, or formed through some other technique. In some embodiments the rigid polymer may include pre-formed cavities prior to coupling with the TPE adhesive tape, while in other embodiments one or more cavities such as cavity 120 may be formed after the TPE adhesive tape is formed on the rigid polymer.

One or more dies, for example, such as die 115 or 315, may then be coupled with the TPE adhesive tape at 510. Specifically, the die may be coupled with the TPE adhesive tape within cavities such as cavity 120.

### EXAMPLES

Example 1 may include a carrier tape comprising: a first layer of thermoplastic elastomer (TPE) adhesive tape; a second layer of rigid polymer that includes a cavity, the rigid polymer coupled with a surface of the TPE adhesive tape such that the TPE adhesive tape is exposed by the cavity; and a die coupled with the TPE adhesive tape within the cavity.

Example 2 may include the carrier tape of example 1, wherein the TPE tape includes styrene-ethylene-butadiene-styrene (SEBS).

Example 3 may include the carrier tape of example 1, wherein the rigid polymer includes polystyrene (PS) or polyethylene (PE).

Example 4 may include the carrier tape of example 1, wherein the TPE adhesive tape has a thickness measured in a direction perpendicular to the surface of less than approximately 100 micrometers (um).

Example 5 may include the carrier tape of any of examples 1-4, wherein the second layer of rigid polymer includes a plurality of cavities, with a die coupled with the TPE adhesive tape in respective ones of the plurality of cavities.

Example 6 may include the carrier tape of any of examples 1-4, wherein a lateral area of the cavity as measured in a direction parallel to the surface is greater than a lateral area of the die such that a portion of the TPE adhesive tape is exposed within the cavity when the die is within the cavity.

Example 7 may include the carrier tape of any of examples 1-4, wherein the second layer of rigid polymer has a thickness measured in a direction perpendicular to the surface that is greater than a thickness of the die.

Example 8 may include a method comprising: forming a first layer of thermoplastic elastomer (TPE) adhesive tape on a second layer of rigid polymer that includes a cavity, the rigid polymer coupled with a surface of the TPE adhesive tape such that the TPE adhesive tape is exposed by the cavity; and coupling a die with the TPE adhesive tape within the cavity.

Example 9 may include the method of example 8, wherein the TPE tape includes styrene-ethylene-butadiene-styrene (SEBS).

Example 10 may include the method of example 8, wherein the rigid polymer includes polystyrene (PS) or polyethylene (PE).

Example 11 may include the method of example 8, wherein the TPE adhesive tape has a thickness measured in a direction perpendicular to the surface of less than approximately 100 micrometers (um).

Example 12 may include the method of any of examples 8-11, wherein the second layer of rigid polymer includes a plurality of cavities, with a die coupled with the TPE adhesive tape in respective ones of the plurality of cavities.

Example 13 may include the method of any of examples 8-11, wherein a lateral area of the cavity as measured in a direction parallel to the surface is greater than a lateral area of the die such that a portion of the TPE adhesive tape is exposed within the cavity when the die is within the cavity.

Example 14 may include the method of any of examples 8-11, wherein the second layer of rigid polymer has a thickness measured in a direction perpendicular to the surface that is greater than a thickness of the die.

Example 15 may include an apparatus comprising: a first layer of thermoplastic elastomer (TPE) adhesive tape that includes a surface, wherein the TPE adhesive tape has a thickness measured in a direction perpendicular to the surface of approximately 100 micrometers (um); and a second layer of rigid polymer that includes a plurality of cavities, the rigid polymer coupled with the surface of the TPE adhesive tape such that the TPE adhesive tape is exposed by the plurality of cavities.

Example 16 may include the apparatus of example 15, wherein the TPE tape includes styrene-ethylene-butadiene-styrene (SEBS).

Example 17 may include the apparatus of example 15, wherein the rigid polymer includes polystyrene (PS) or polyethylene (PE).

Example 18 may include the apparatus of any of examples 15-17, further comprising a plurality of dies, respective dies of the plurality of dies coupled with the TPE adhesive tape within respective cavities of the plurality of cavities.

Example 19 may include t e apparatus of example 18, wherein a lateral area of a cavity of the plurality of cavities as measured in a direction parallel to the surface is greater than a lateral area of a die of the plurality of dies such that a portion of the TPE adhesive tape is exposed within the cavity when the die is within the cavity.

Example 20 may include the apparatus of example 18, wherein the second layer of rigid polymer has a thickness measured in a direction perpendicular to the surface that is greater than a thickness of a die of the plurality of dies.

Various embodiments may include any suitable combination of the above-described embodiments including alternative (or) embodiments of embodiments that are described in conjunctive form (and) above (e.g., the “and” may be “and/or”). Furthermore, some embodiments may include one or more articles of manufacture (e.g., non-transitory computer-readable media) having instructions, stored thereon, that when executed result in actions of any of the above-described embodiments. Moreover, some embodiments may include apparatuses or systems having any suitable means for carrying out the various operations of the above-described embodiments.

The above description of illustrated implementations, including what is described in the Abstract, is not intended to be exhaustive or to limit the embodiments of the present disclosure to the precise forms disclosed. While specific implementations and examples are described herein for illustrative purposes, various equivalent modifications are possible within the scope of the present disclosure, as those skilled in the relevant art will recognize.

These modifications may be made to embodiments of the present disclosure in light of the above detailed description. The terms used in the following claims should not be construed to limit various embodiments of the present disclosure to the specific implementations disclosed in the specification and the claims. Rather, the scope is to be determined entirely by the following claims, which are to be construed in accordance with established doctrines of claim interpretation.

We claim:

1. A carrier tape comprising:
a first layer of thermoplastic elastomer (TPE) adhesive tape;
a second layer of rigid polymer that includes a cavity, the rigid polymer coupled with a surface of the TPE adhesive tape such that the TPE adhesive tape is exposed by the cavity; and
a die coupled with the TPE adhesive tape within the cavity.

2. The carrier tape of claim 1, wherein the TPE tape includes styrene-ethylene-butadiene-styrene (SEBS).

3. The carrier tape of claim 1, wherein the rigid polymer includes polystyrene (PS) or polyethylene (PE).

4. The carrier tape of claim 1, wherein the TPE adhesive tape has a thickness measured in a direction perpendicular to the surface of less than approximately 100 micrometers (um).

5. The carrier tape of claim 1, wherein the second layer of rigid polymer includes a plurality of cavities, with a die coupled with the TPE adhesive tape in respective ones of the plurality of cavities.

6. The carrier tape of claim 1, wherein a lateral area of the cavity as measured in a direction parallel to the surface is greater than a lateral area of the die such that a portion of the TPE adhesive tape is exposed within the cavity when the die is within the cavity.

7. The carrier tape of claim 1, wherein the second layer of rigid polymer has a thickness measured in a direction perpendicular to the surface that is greater than a thickness of the die.

8. A method comprising:
forming a first layer of thermoplastic elastomer (TPE) adhesive tape on a second layer of rigid polymer that includes a cavity, the rigid polymer coupled with a surface of the TPE adhesive tape such that the TPE adhesive tape is exposed by the cavity; and
coupling a die with the TPE adhesive tape within the cavity.

9. The method of claim 8, wherein the TPE tape includes styrene-ethylene-butadiene-styrene (SEBS).

10. The method of claim 8, wherein the rigid polymer includes polystyrene (PS) or polyethylene (PE).

11. The method of claim 8, wherein the TPE adhesive tape has a thickness measured in a direction perpendicular to the surface of less than approximately 100 micrometers (um).

12. The method of claim 8, wherein the second layer of rigid polymer includes a plurality of cavities, with a die coupled with the TPE adhesive tape in respective ones of the plurality of cavities.

13. The method of claim 8, wherein a lateral area of the cavity as measured in a direction parallel to the surface is greater than a lateral area of the die such that a portion of the TPE adhesive tape is exposed within the cavity when the die is within the cavity.

14. The method of claim 8, wherein the second layer of rigid polymer has a thickness measured in a direction perpendicular to the surface that is greater than a thickness of the die.

15. An apparatus comprising:
a first layer of thermoplastic elastomer (TPE) adhesive tape that includes a surface, wherein the TPE adhesive tape has a thickness measured in a direction perpendicular to the surface of approximately 100 micrometers (um); and
a second layer of rigid polymer that includes a plurality of cavities, the rigid polymer coupled with the surface of the TPE adhesive tape such that the TPE adhesive tape is exposed by the plurality of cavities.

16. The apparatus of claim 15, wherein the TPE tape includes styrene-ethylene-butadiene-styrene (SEBS).

17. The apparatus of claim 15, wherein the rigid polymer includes polystyrene (PS) or polyethylene (PE).

18. The apparatus of claim 15, further comprising a plurality of dies, respective dies of the plurality of dies coupled with the TPE adhesive tape within respective cavities of the plurality of cavities.

19. The apparatus of claim 18, wherein a lateral area of a cavity of the plurality of cavities as measured in a direction parallel to the surface is greater than a lateral area of a die of the plurality of dies such that a portion of the TPE adhesive tape is exposed within the cavity when the die is within the cavity.

20. The apparatus of claim 18, wherein the second layer of rigid polymer has a thickness measured in a direction perpendicular to the surface that is greater than a thickness of a die of the plurality of dies.
